(19) United States
(12) Patent Application Publication
(10) Pub. No.: US 2026/0026388 A1
(43) Pub. Date: Jan. 22, 2026

(54) METHOD FOR PRODUCING AN SMD POWER SEMICONDUCTOR COMPONENT MODULE AND SMD POWER SEMICONDUCTOR COMPONENT MODULE

(71) Applicant: iCuTech - Anlagenbau GmbH, Nürnberg (DE)

(72) Inventor: Christian Göbl, Nürnberg (DE)

(21) Appl. No.: 18/993,193

(22) PCT Filed: Jun. 19, 2023
(86) PCT No.: PCT/EP2023/066402

§ 371 Date: Jan. 10, 2025

(30) Foreign Application Priority Data
Jul. 12, 2022 (DE) 10 2022 117 352.6
Apr. 24, 2023 (DE) 10 2023 110 340.7

(51) Int. Cl. H01L 21/603; H01L 21/60

(52) U.S. Cl. CPC H01L 21/603; H01L 2021/60292

(57) ABSTRACT

A method for producing an SMD power semiconductor component module includes providing an SMD circuit carrier equipped with contact points and an insulation, and at least one discrete power semiconductor component equipped with electrically conductive connection elements, preferably connection legs. The at least one discrete power semiconductor component, equipped with electrically conductive connection elements, is arranged on the side of the SMD circuit carrier equipped with the contact points. The connection elements of the power semiconductor component contact the contact points of the SMD circuit carrier, and the connection elements are connected to the respectively assigned contact points by laser welding.

The present invention relates to a method for producing an SMD power semiconductor component module, in which at least one discrete power semiconductor component equipped with electrically conductive connection elements is mounted on an SMD circuit carrier in SMD design equipped with contact points. The mechanical fastening and electrical contacting is carried out on the same side of the SMD circuit carrier. Furthermore, the present invention relates to an SMD power semiconductor component module that has been produced using the method according to the invention.

### TECHNOLOGICAL BACKGROUND

Nowadays, discrete SMD power semiconductor components are used in large quantities as SMD components and soldered onto SMD circuit carriers, e.g. onto printed circuit boards (PCBs) or IMS substrates, using the soft soldering process. In this process, all three contacts of the component, namely collector, emitter and gate, are soldered to a power line of the SMD circuit carrier. As the performance of power semiconductor chips increases, so does the amperage, meaning that newer power semiconductor chips have a higher current carrying capacity. The higher currents in these components cause the contacts to heat up more, which reduces reliability of the applications. The type of connection of the contacts in the power semiconductor component thus determines the current carrying capacity of the power semiconductor component. This means that the current must be reduced or limited if necessary in order to ensure the required reliability of the circuit. This is particularly relevant when the power circuit is constructed using SMD components on circuit carriers, which, in contrast to PCBs, can also assume an enhanced cooling function for the circuit. In this case, the small copper cross-sections of the connection legs and the additional ohmic resistances due to the soft solder connection cause losses that hinder the economic utilization of the current carrying capacity of the chips or reduce the reliability of the circuit.

### Published Prior Art

A method according to the preamble of claim 1 is known from DE 10 2013 213 448 B4. Here, power semiconductors are attached to the top side of a substrate, the underside of which is connected to a heat sink. The electrical connection of the power semiconductors and the contact points of the substrate are made by soldering in a reflow process.

A heat sink module for electronic semiconductor devices is known from EP 2 458 632 A1, in which a plurality of electronic semiconductor devices are fixed to a dissipating body equipped with fins by means of a fastening frame, leaf springs and fastening screws. The fastening frame determines the exact arrangement of the individual semiconductor devices. The connection legs of the electronic semiconductor devices extend vertically through a printed circuit board and are connected to the PCB on the side opposite the heat sink module by wave welding or point-to-point welding. The mechanical fastening plane and electrical connection plane of the electronic semiconductor devices are therefore located on different sides of the printed circuit board.

A power module with packaged power semiconductors for the controllable supply of electrical power to a consumer is known from DE 10 2019 205 772 A1. A heat sink with a cooling surface is arranged on the underside of a printed circuit board for cooling. The power semiconductors are fastened directly to the heat sink and protrude through through-holes that must be provided in the circuit board. The connection elements of the power semiconductors are electrically connected to connection surfaces on the side of the printed circuit board facing away from the heat sink. Soldering, in particular split head soldering, but also welding is mentioned as a possible connection. However, this is not an SMD power semiconductor component, as the power semiconductor is fastened directly to the heat sink. The power semiconductors must be equipped with insulation on the underside, as they are fastened directly to the top side of the heat sink.

### Object of the Present Invention

The object of the present invention is to provide a method which allows SMD power semiconductor component modules with high current carrying capacity to be produced using simple production technology.

### To Achieve the Object

The above object is achieved by the features of claim 1. Advantageous embodiments of the method according to the invention are claimed in the dependent claims. An SMD power semiconductor component module according to the invention is taught in claim 25.

The method according to the invention for producing an SMD power semiconductor device module comprises the following steps:
providing an SMD circuit carrier equipped with contact points and an insulation or an insulator;
providing at least one discrete power semiconductor component equipped with electrically conductive connection elements;
arranging the at least one discrete power semiconductor component, equipped with electrically conductive connection elements, on the side of the SMD circuit carrier equipped with the contact points, wherein the connection elements of the power semiconductor component contact the contact points of the SMD circuit carrier; and
connecting the connection elements to the respectively assigned contact points by laser welding.

Preferably, power semiconductor components with an electrical contacting on the underside (i.e. without insulation) are used in the method according to the invention.

Preferably, the SMD circuit carrier includes a cooling function.

Preferably, a printed circuit board, a so-called IMS substrate or a lead frame is provided as the SMD circuit carrier. The IMS substrate is a conductor track structure on an insulator. Lead frames are metallic grids, e.g. punched grids, which represent conductor tracks. Said lead frames can be insulated and/or equipped with a cooling structure or a heat sink or a cooling layer.

In the course of the method according to the invention, the power semiconductor component is thus fastened in SMD design to the same side of the SMD circuit carrier on which the electrical contacting of the connection elements thereof to the SMD circuit carrier takes place. The mechanical fastening plane and electrical contacting plane are thus the same or at least parallel to one another on one and the same side of the SMD circuit carrier. This considerably simplifies the assembly of SMD power semiconductor component modules. Moreover, due to connecting the connection elements to the respectively assigned contact points by laser welding instead of soldering, the current carrying capacity of the SMD power semiconductor component module is significantly improved. During laser welding, the connection elements and contact points are melted in the relevant area of the laser beam, resulting in a close connection between the joining partners. Laser welding can thus be used to produce a monometallic bond. This results in the advantage that this type of materially bonded connection allows the SMD power semiconductor component module to be operated at higher amperages in contrast to soldered connections. In addition, the connection according to the invention also allows the SMD power semiconductor component module to be operated at higher temperatures compared to the temperatures possible with a soldered connection. Furthermore, compared to a soldered connection, more sustainable operation under high load cycle conditions is possible. This enables a high level of reliability of the SMD power semiconductor component module to be achieved. Moreover, it is achieved that the power semiconductor component module can be operated at the full performance capacity of its power semiconductor components, i.e. that no “limiting” has to be applied.

The contacting (of the contact point and the connection element) is a standard contacting for a soldered connection, in which the contact point and/or the connection element is/are made of copper or a copper alloy. As a result, the method according to the invention can be applied to conventional semiconductor components (e.g. TO 263; D²Pack, SO-8) or circuit carriers (e.g. printed circuit boards, PCBs, DCB substrates, IMS substrates, lead frames), in which appropriate contacting is still provided. This is particularly advantageous when the power circuit is constructed using SMD components on IMS substrates, which, in contrast to PCBs, can also assume an enhanced cooling function for the circuit. In this case, small copper cross-sections of the connections and the additional ohmic resistances in their conventional soft soldering would lead to losses that hinder the economic utilization of the current carrying capacity of the chips or reduce the reliability of the circuit. This can be effectively avoided by the invention. The contact point and/or the connection element can be pre-tinned.

It is advantageous if the connection element in the area of the connection element where laser welding takes place is designed to run parallel to the main extension surface of the SMD circuit carrier.

Preferably, the connection elements are so-called connection legs, which have particularly small connection cross-sections. Here, the method according to the invention is particularly advantageous, as the laser-welded connection causes lower ohmic resistance compared to a soldered connection.

Preferably, the laser-welded connection of the power semiconductor component can only be limited to the area of the connection legs. Preferably, no laser-welded connection is provided in the area of the further contact area on the underside of the power semiconductor component with the SMD circuit carrier.

The connection legs are preferably designed in a stepped manner so that, on the one hand, they run parallel to the connection plane in the area to be welded and/or are adapted to the overall height of the arrangement. On the other hand, this creates the advantage that the laser beam can couple from above undisturbed and evenly on the area to be welded.

Studies have shown that it is particularly advantageous if the laser-welded connection is formed by a continuous melting area. This enables a uniform energy input with a small contact surface due to the narrow connection legs, thus creating an effective and stable contacting.

It is particularly advantageous if, alternatively or additionally, the laser-welded connection is made using a wobbling laser beam. This also increases the area of coupling of the laser beam and thus prevents excessive local melting, which can lead to holes.

Laser welding is preferably carried out with an IR laser. The use of an IR laser has proven to be very advantageous, as its use initially forms an oxide, in particular copper oxide, on the surface of the welding point, which reduces the degree of reflection for the laser beam and thus improves the coupling of the laser beam and its energy.

According to a further embodiment, the at least one discrete power semiconductor component equipped with electrically conductive connection elements, preferably the plurality of power semiconductor components, can be located between the SMD circuit carrier and a holding part.

The at least one discrete power semiconductor component equipped with electrically conductive connection elements, preferably the plurality of power semiconductor components, can first be positioned and fixed on the holding part prior to laser welding due to a particular embodiment of the method according to the invention. In this case, the holding part acts as a transfer part. Here, the discrete power semiconductor component or the plurality of discrete power semiconductor components can already be fixed to the holding part in a particular arrangement, for example in a circular or star-shaped arrangement. This may be a definitive arrangement in a specific application to be determined in advance. In an expedient embodiment, the holding part can remain on the power semiconductor component module to be produced such that the power semiconductor components are securely stabilized in their position during subsequent laser welding. The holding part also serves as a mechanical bearing in the overall arrangement.

In an alternative embodiment of the invention, the at least one discrete power semiconductor component or the plurality of discrete power semiconductor components can be grasped by a gripper and positioned on the power semiconductor component module to be produced in a particular arrangement, for example in a circular or star-shaped arrangement. The holding part is then used to fix the respective power semiconductor component in position only during laser welding. The holding part can then be removed again. In this case, the holding part only acts as a temporary holder during laser welding.

The power semiconductor components can be fixed to the holding part by gluing, for example by means of adhesive dots on the upper sides of the power semiconductor components.

Advantageously, the holding part has welding windows through which the laser welding takes place. This allows an advantageous coupling of the laser beam from above to be carried out. At the same time, other areas of the SMD circuit carrier are protected or shielded from being affected by the laser beam. In particular, welding residues can be retained here due to the shielding. In addition, the presence of welding windows enables the introduction of insulating material onto the welding points or the introduction of a casting compound, provided that the entire volume, which is also formed or at least limited by the holding part, can be poured out.

Moreover, a pressure contact for electrical and thermal contacting in the SMD power semiconductor component module can be created between the at least one power semiconductor component and the SMD circuit carrier via the holding part by clamping the arrangement of power semiconductor component and circuit carrier between the holding part and a counter bearing which is preferably located on the installation side. The latter can, for example, be a heat sink located on the underside of the SMD circuit carrier or a counter bearing located on the installation side, e.g. a housing part with which the power semiconductor module is installed in use. Moreover, due the use of the holding part for clamping the respective power semiconductor component it is no longer necessary to adapt the shape or embodiment of the power semiconductor component itself, for example, to press it in. The power semiconductor component itself does not have to be adapted, but only has to rest on the conductor track structure of the SMD circuit carrier located on the insulator. The pressure contact can be achieved in particular, for example, by screwing the holding part to the heat sink or by pressing the holding part to the SMD circuit carrier. The pressure contact creates a reliable electrical and thermal contacting between the power semiconductor component and the SMD circuit carrier, which always ensures good electrical and thermal contact in the event of temperature fluctuations or mechanical influences.

According to a further expedient embodiment, an elastic element can be arranged between the at least one power semiconductor component and the holding part. This ensures that the power semiconductor components are pressed onto the SMD circuit carrier with the same or at least similar force. In addition, this embodiment enables a pressure contact to be created by clamping, using the holding part, even if there are height differences due to power semiconductor components of different heights.

Expediently, the elastic element is a silicone foam pad.

The at least one power semiconductor component, preferably a plurality of power semiconductor components, can first be positioned in a predetermined arrangement and/or orientation on a, preferably self-adhesive, placement foil and fixed there, wherein the holding part can then be fixed on the at least one power semiconductor component, preferably on the plurality of power semiconductor components, in the arrangement and/or orientation previously determined on the placement foil. The method according to the invention thus makes it possible to assemble the arrangement of power semiconductor components in advance, e.g. on an industrial scale, before the arrangement is transferred to a holding part to be used as a transfer part or is removed by a gripper. For example, such a plurality of arrangements and/or orientations of a plurality of power semiconductor components can be provided on a supply roll for the production process.

The foil is removed from the holding part to be used as a transfer part after the power semiconductor components have been fixed to the latter.

Preferably, the foil is a self-adhesive foil.

The method according to the invention also makes it possible for the power semiconductor device module to be designed with a low-inductance interconnection level. A low-inductance interconnection level enables fast switching in particular. In particular, a multilayer SMD circuit carrier comprising at least a first and second insulator as well as a first and second conductor track structure can also be produced as an SMD circuit carrier as part of the method according to the invention, wherein the contact point can be located on the first conductor track structure or second conductor track structure. A structure with more than two insulators or insulation layers can also be produced.

The method according to the invention also allows the second isolator with the second conductor track structure to be arranged laterally with respect to the semiconductor component. Here too, laser welding of the connection elements of the power semiconductor component to the laterally arranged second conductor track structure can be carried out in the manner according to the invention.

In particular, the contact point may be located at the second conductor track structure, wherein the second insulator with the second conductor track structure is angled and the first conductor track structure is also angled correspondingly or in accordance with the second insulator and is continued by the latter. Here, the contacting is located in the area of the second conductor track structure arranged parallel to the first insulator.

To fulfill the cooling function, a cooler, preferably in the form of a heat sink, can expediently be arranged below the SMD circuit carrier for heat dissipation. In particular, a heat sink made of aluminum, preferably pure aluminum, can be provided due to its high thermal conductivity. With these cooling apparatuses and conditions, the semiconductor chips contained in the semiconductor components can meet optimum performance and reliability requirements.

With particular advantage, the semiconductor component can be designed for a minimum amperage of 5 A or for a minimum voltage of 24 V. The method according to the invention is particularly suitable for this field of power electronics, as the laser-welded connection allows for the high temperatures caused by the high amperages and voltages of the semiconductor components and does not limit the performance and reliability of the circuit.

The semiconductor component can be an active or passive component. (Packaged) discrete power components are used as active and passive semiconductor components, which can be selected according to the requirements of the circuit based on the corresponding parameters. The semiconductor chips they contain are designed to meet optimum performance and reliability requirements under the given cooling conditions. Further (passive) circuit components can also be welded or pressure-contacted.

The semiconductor component can have an electrically and thermally conductive base surface that can be contacted with the SMD circuit carrier or the conductor track structure arranged on it by means of pressure contact. For this purpose, for example, a circumferential frame of the holding part can be pressed with an edge area of the insulator. In particular, the holding part can have at least one projection that engages in a corresponding recess on the edge area of the insulator for pressing or vice versa. In particular, the parts may also be designed to latch or snap into place. The pressure contact can be reliably and permanently established with the necessary pressure or pressing force by means of pressing or the latch or snap connection.

Advantageously, the electrically and thermally conductive base surface of the semiconductor component can be equipped with a coating of silver or a silver alloy, whereby a good ohmic as well as thermal contact is permanently realized. A good ohmic contact ensures good current conduction and a good thermal contact ensures good heat dissipation and therefore appropriate cooling.

The coating made of silver or a silver alloy can have a thickness of 0.1 μm to 0.5 μm, in particular of 0.1 μm to 0.3 μm.

The present invention further relates to an SMD power semiconductor component module produced by a method according to at least one of claims 1 to 24.

### DESCRIPTION OF THE INVENTION USING EXEMPLARY EMBODIMENTS

The invention is discussed in more detail with reference to exemplary embodiments in the drawing figures. In the figures:

FIG. 1 shows a highly simplified schematic representation of the provision of a plurality of power semiconductor components in a specific arrangement and/or orientation on a placement foil;

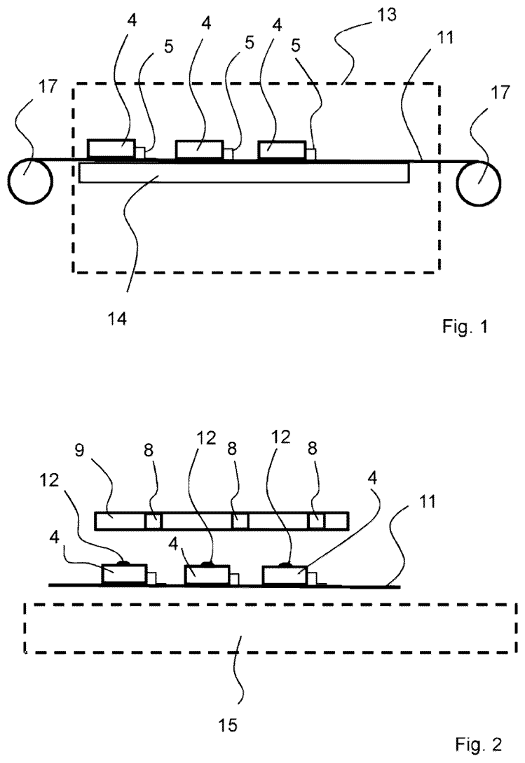

FIG. 2 shows a highly simplified schematic representation of the transfer of the power semiconductor components arranged on the placement foil in the relevant arrangement and/or orientation to a holding part, which in this example serves as a transfer part;

FIG. 3 shows a highly simplified schematic representation of laser welding for connecting connection elements of the power semiconductor component to contact points of an SMD circuit carrier in the form of a lead frame;

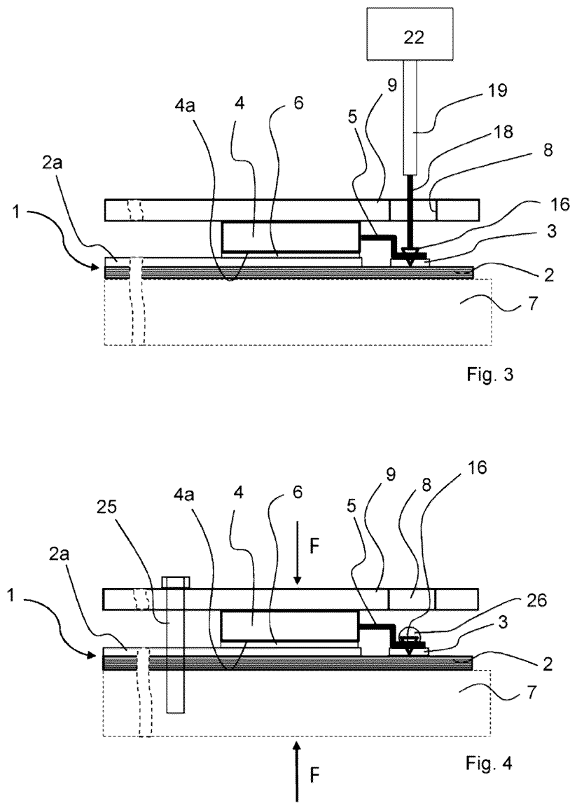

FIG. 4 shows a highly simplified schematic representation of the arrangement, as shown in FIG. 3, after completion;

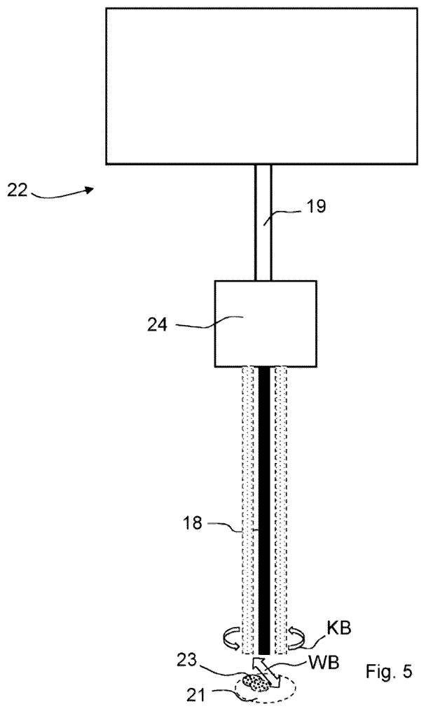

FIG. 5 shows a highly simplified schematic representation of the laser during the implementation of the laser welding connection;

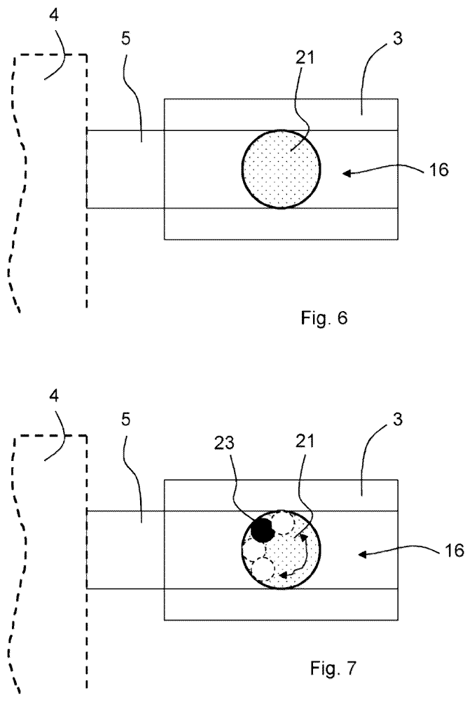

FIG. 6 shows a highly simplified schematic representation of the melting area in the area of the connection element of the power semiconductor component and the contact point of the SMD circuit carrier in a first embodiment;

FIG. 7 shows a highly simplified schematic representation of the melting area in the area of the connection element of the power semiconductor component and the contact point of the SMD circuit carrier in a further embodiment;

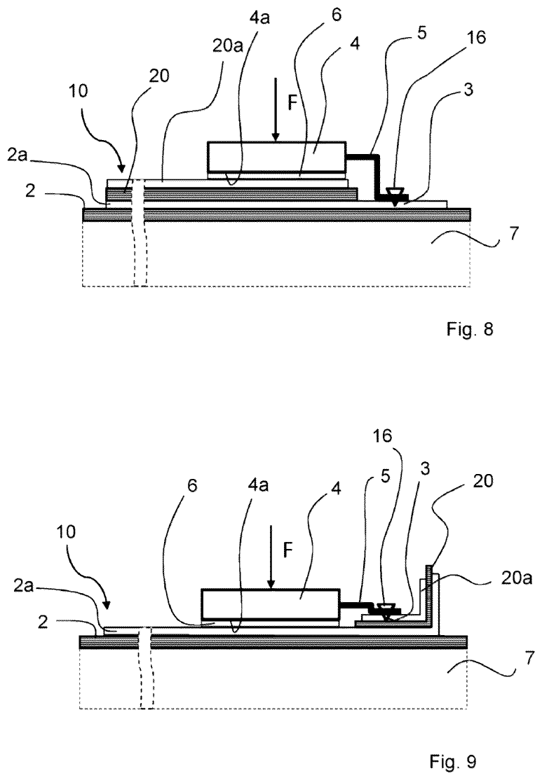

FIG. 8 shows a highly simplified schematic representation of a further embodiment of an SMD power semiconductor component module produced using the method according to the invention in the area of a power semiconductor component in the form of a lead frame with two insulators;

FIG. 9 shows a highly simplified schematic representation of a further embodiment of an SMD power semiconductor component module produced using the method according to the invention in the area of a power semiconductor component in the form of a lead frame with two insulators;

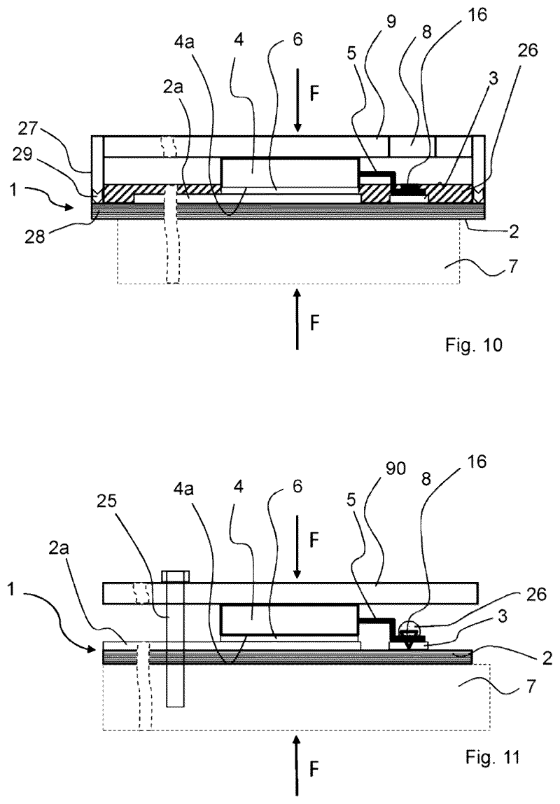

FIG. 10 shows a highly simplified schematic representation of the arrangement, as shown in FIG. 4, with the holding part latched or pressed with the insulator;

FIG. 11 shows a highly simplified schematic representation of a further embodiment of an SMD power semiconductor component module produced using the method according to the invention in the area of a power semiconductor component with a holding part which has been applied after laser welding has been carried out in order to create a pressure contact;

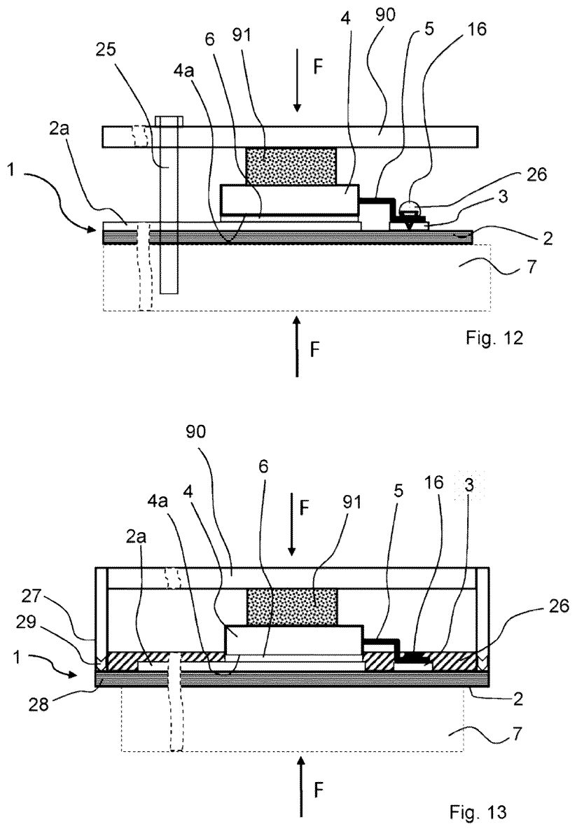

FIG. 12 shows a highly simplified schematic representation of a further embodiment of an SMD power semiconductor component module produced using the method according to the invention in the area of a power semiconductor component module using an elastic element between the holding part and the power semiconductor component to create a pressure contact;

FIG. 13 shows a highly simplified schematic representation of the arrangement according to FIG. 10 with additional use of an elastic element and a holding part which is not provided as a transfer part; and

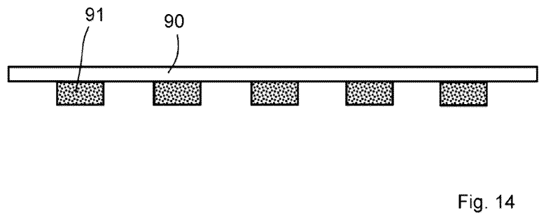

FIG. 14 shows a highly simplified schematic representation of a holding part for ensuring a pressure contact for a plurality of power semiconductor components arranged on an SMD circuit carrier.

FIG. 1 shows the provision of a plurality of power semiconductor components 4 which are not insulated on their underside in a placement machine 13 on a placement foil 11 which is pulled off a roll 17 and rewound onto another roll 17 with the power semiconductor components 4 arranged on it. The power semiconductor components 4 are discrete power semiconductor components with connection elements 5 in the form of connection legs. Typically, each power semiconductor component 4 is provided with one connection leg each for the collector, the emitter and the gate of the power semiconductor component 4. The placement machine 13 comprises a metallic carrier plate 14, for example. The metallic carrier plate 14 causes an electrostatic discharge of the power semiconductor components 4.

The placement foil 11 is preferably a one-sided self-adhesive foil.

In the course of placing the power semiconductor components 4 on the placement foil 11, an arrangement and/or orientation of the power semiconductor components 4 can thus be determined as they are to be provided for later use as required. Consequently, this is an arrangement and/or orientation of the power semiconductor components 4 to one another or among one another that can already be pre-assembled as part of the provision of the plurality of power semiconductor components 4. For example, this can be a ring-shaped or star-shaped arrangement. This enables large-scale pre-assembly of power semiconductor component groups. The grouped power semiconductor components can be provided together with the placement foil 11 in form of a roll.

According to the method according to the invention, the assembly of power semiconductor components 4 arranged on the placement foil 11 is transferred to a holding part 9, positioned on the latter and fixed. This is carried out on an equipment plate 15. The placement foil 11 is provided on the equipment plate 15 together with the power semiconductor components 4 located thereon. Adhesive 12 is applied to the upper side of each power semiconductor component 4, and then the holding part 9 is applied to the upper side of the respective power semiconductor component 4 equipped with adhesive 12. This permanently connects the holding part 9 to the pre-assembled arrangement of power semiconductor components 4. The placement foil 11 is then removed. The holding part 9 is equipped with individual welding windows 8. Preferably, the holding part 9 is a plastic plate or a plate-shaped part of a component for a later purpose of application.

FIG. 3 shows the contacting of a power semiconductor component 4, which is already connected to the holding part 9, to an SMD circuit carrier 1 in the form of a lead frame using a laser-welded connection. It should be noted that FIG. 3 only shows a partial area of a holding part 9 provided in the manufacturing process.

The lead frame comprises an insulator 2 as well as a conductor track structure 2a or contact points 3 located on the insulator 2 for contacting to the connection elements 5 of the power semiconductor components 4. The conductor track structure of the lead frame can be punched, etched or laser-cut. The respective power semiconductor component 4 has an electrically conductive base surface 4a on which a coating 6 is located. The coating 6 is preferably a coating made of silver or a silver alloy. The coating made of silver or a silver alloy can have a thickness of 0.1 μm to 0.5 μm, in particular 0.1 μm to 0.3 μm.

A cooler 7 is positioned on the underside of the insulator 2, which serves to dissipate the thermal energy generated during operation of the power semiconductor components 4.

Instead of the SMD circuit carrier 1 in the form of a lead frame, an SMD circuit carrier in the form of a printed circuit board or an IMS substrate could also be used.

The arrangement of the power semiconductor components 4 and the holding part 9 adhering thereto is aligned with the SMD circuit carrier 1 such that the connection elements 5 of the respective power semiconductor component 4 are located at the contact points 3 of the SMD circuit carrier 1. Here, the connection elements 5 of the power semiconductor component 4 are preferably designed in a stepped manner and, in the contact area with the contact point 3, run parallel to the main extension surface of the SMD circuit carrier 1.

The contact point 3 and the connecting element 5 are made of a material comprising copper or a copper alloy. The connection elements 5 of the power semiconductor components 4 can be equipped with a Sn-Ag coating (not shown in the figures). The latter is usually provided as a soldering aid in order to avoid copper oxides in the soldering process that usually takes place.

In the context of the method according to the invention, contacting between the connection element 5 and the contact point 3 is not created by means of soldering, but by means of a laser-welded connection 16.

In the course of the method according to the invention, the power semiconductor component 4 in SMD design is fastened to the same side of the SMD circuit carrier 1 on which the electrical contacting of the connection elements 5 thereof to the SMD circuit carrier 1 takes place. The mechanical fastening plane and electrical contacting plane are thus the same or at least parallel to one another on one and the same side of the SMD circuit carrier 1. Due to connecting the connection elements 5 to the respectively assigned contact points 3 using the laser-welded connection 16 instead of a soldered connection, the current carrying capacity of the produced SMD power semiconductor component module is significantly improved. During laser welding, the connection elements and contact points are melted in the relevant area of the laser beam, resulting in a close connection between the joining partners. In contrast to soldering, laser welding produces a monometallic connection. This results in the advantage that this type of materially bonded connection allows the SMD semiconductor component module to be operated at higher amperages in contrast to a soldered connection. In addition, the connection according to the invention also allows the SMD power semiconductor component module to be operated at higher temperatures compared to the temperatures possible with a soldered connection. Furthermore, compared to a soldered connection, more sustainable operation under high load cycle conditions is possible. This enables a high level of reliability of the SMD power semiconductor component module to be achieved. Finally, it is achieved that the power semiconductor component module can be operated at the full performance capacity of its power semiconductor components, i.e. that no “limiting” has to be applied.

Due to the holding part 9 arranged on the upper side with the welding windows 8 formed therein, an advantageous coupling of the laser beam 18 from above can be carried out. At the same time, other areas of the SMD circuit carrier 1 are protected or shielded from being affected by the laser beam 18, in particular from welding residues. Moreover, the welding windows 8 enable the introduction of insulating material 26 (in FIG. 4, for example, in the form of insulating droplets) in the area of the laser welding or the introduction of insulating material 26 in the form of a casting compound by completely casting a cavity that is at least partially delimited by the holding part 9, as shown in FIG. 10 by way of example.

According to an expedient alternative embodiment of the method according to the invention, at least one power semiconductor component, preferably a plurality of power semiconductor components, can be removed by a gripper (not shown in the drawing figures) from a provision, e.g. a correspondingly populated placement foil 11, in a desired arrangement and arranged on the SMD circuit carrier. In such a procedure, the holding part 9, as shown in FIG. 3, is used to locally fix the power semiconductor components 4 during the laser welding process. In this case, the holding part 9 is not used as a transfer part, but only for fixing during laser welding.

As shown in FIG. 4, a pressure contact can be created between the power semiconductor component 4 and the SMD circuit carrier 1 by means of the holding part 9 for electrical and thermal contacting. As shown in FIG. 4, this can be carried out by the holding part 9 and the SMD circuit carrier 1 clamping the power semiconductor component 4. This can be carried out, for example, by screwing the holding part 9 to the cooler 7 using screws 25. It should be noted that, for the sake of simplicity, only one screw 25 is shown in FIG. 4. The entire arrangement comprising the holding part 9, the power semiconductor components 4, the SMD circuit carrier 1 as well as the cooler 7 can, for example, be arranged on a bearing cover of an electrical device, e.g. an electric motor. For example, certain electrical consumers or electrical components (e.g. motor coils) can be connected directly to the SMD power semiconductor component module prepared in this way.

Alternatively, the holding part 9 can also be pressed with the SMD circuit carrier 1 to create the pressure contact. For this purpose, for example, a circumferential frame 27 of the holding part 9 can be pressed with an edge area 28 of the insulator 2. The pressure contact can be reliably and permanently established with the necessary pressure or pressing force by means of pressing or the latch or snap connection. In particular, a latching or snapping in of the parts may also be provided (see FIG. 10). A press connection and/or latch connection is indicated by reference number 29. In particular, the holding part 9 can have at least one projection (not shown in FIG. 10), which engages or latches or snaps into a corresponding recess (also not shown in FIG. 10) on the edge area 28 of the insulator 2, or vice versa. The pressure contact can be reliably and permanently established with the necessary pressure or pressing force by means of the press, latch and/or snap connection.

FIG. 5 shows a highly simplified schematic representation of the embodiment and mode of operation of the laser to be used in order to produce the laser-welded connection 16. Preferably, this is a so-called fiber laser 22, in which the laser beam 18 is provided via an optical fiber 19. A scanner 24 can be used to move the laser beam 18 according to the required purpose of application. The scanner 24 can ensure that the laser beam 18 carries out, for example, a circular movement (KB) around a central axis, as shown in FIG. 5. Alternatively or additionally, the laser beam 18 can also carry out a wobbling movement (WB), as also shown in FIG. 5.

FIG. 5 shows an example of a coupling surface 23 of the laser beam 18 in a snapshot during the circular movement KB as well as during the wobbling movement WB. Preferably, the laser is an IR laser.

The focal spot of the laser has a diameter in the range of 20-50 μm, in particular 30-40 μm. The melting area 21 caused by the laser beam 18 is formed at least substantially continuous, for example in the form of a dot or circle. The diameter of the melting area 21 is in the range of 60-100 μm, preferably 70-90 μm.

FIG. 6 shows a highly simplified schematic representation of the laser-welded connection 16, which has at least substantially a circular melting area 21. In the representation shown in FIG. 6, the at least substantially dot-shaped or circular shape of the melting area 21 is caused by the substantially circular cross-section of the laser beam 18.

In the alternative embodiment shown in FIG. 7, an at least substantially dot-shaped or circular melting area 21 is also provided. However, the latter is due to the particular movement of the laser beam 18, namely a circular movement KB, see FIG. 5. The circular movement can be superimposed by a wobbling movement WB.

FIG. 8 shows a highly simplified schematic representation of a power semiconductor component module produced according to the method of the invention with a low-inductance structure comprising a multilayer SMD circuit carrier 10 in the form of a multilayer lead frame. The multilayer SMD circuit carrier 10 shown in FIG. 8 comprises a first insulator 2 assigned to the cooler 7 with a punched or cut conductor track structure 2a and contact points 3 and a second insulator 20 located thereon with an associated punched or cut conductor track structure 20a. The connection element 5 of the power semiconductor component 4 contacts the contact point 3 of the conductor track structure 2a. A corresponding structure enables particularly fast switching behavior of the electronic circuit.

FIG. 9 shows a highly simplified schematic representation of a further variant of a power semiconductor component module which can be produced in accordance with the method according to the invention. Here, this is also a multilayer SMD circuit carrier 1 in the form of a multilayer lead frame, which has a first insulator 2 equipped with a conductor track structure 2a, which is connected to the cooler 7, as well as a second insulator 20 located thereon, which is equipped with a second conductor track structure 20a and is formed in an angled manner. Here, the respective connection element 5 of the power semiconductor component 4 is contacted with the contact point 3 of the second conductor track structure 20a of the second insulator 20 by means of a laser-welded connection 16.

In the power semiconductor component module shown in FIGS. 8 and 9, a multilayer printed circuit board or a multilayer IMS substrate could also be used instead of an SMD circuit carrier 10 in the form of a multilayer lead frame.

Otherwise, the two embodiments of the power semiconductor component modules correspond to the power semiconductor component module in FIG. 4. The two embodiments in FIGS. 8 and 9, in the ready-to-use state, also comprise a holding part 9 arranged on the upper side, with which a pressure contact can be created in the manner already described for FIG. 4.

In the embodiment shown in FIG. 11, in contrast to the embodiment shown in FIG. 4, the pressure contact is exerted on the power semiconductor component 4 by means of a holding part 90 which has no through-holes for the laser beam. In this embodiment, the laser welding of the connection elements 5 of the power semiconductor component 4 was carried out before the holding part 90 was attached. The laser welding could, for example, have been carried out by using a holding part 9 with a welding window 8, which was only temporarily provided for fixing the power semiconductor component 4 during laser welding and which was subsequently removed again. As a result, the holding part 90 shown in FIG. 11 does not require a welding window. Furthermore, the embodiment as shown in FIG. 11 corresponds to the embodiment of the invention as shown in FIG. 4.

FIG. 12 shows a further embodiment of the respective present invention, in which an elastic element 91 is inserted between the holding part 90 and the respective power semiconductor component 4 by means of which a controlled pressure is applied to the power semiconductor component 4 to ensure the pressure contact. Expediently, the elastic element 91 is a silicone foam pad. By means of the elastic element 91, a homogenized contact pressure can be applied to a plurality of power semiconductor components 4 via the holding part 90.

In the same way, it is also possible that, if a holding part 9 equipped with welding windows 8 is to be used instead of the holding part 90 in order to exert a pressure contact, a corresponding elastic element 91 can also be present.

Furthermore, the embodiment as shown in FIG. 13 shows a possible modification of the embodiment as shown in FIG. 10, in which, for one, an elastic element 91 is arranged between the holding part 90, in which there are no welding windows compared to FIG. 10, and the power semiconductor component 4. Accordingly, an elastic element 91 can also be present in the embodiment shown in FIG. 10.

FIG. 14 shows a holding part 90, in which a plurality of elastic elements 91 are provided for applying pressure to a plurality of power semiconductor components (not shown in FIG. 14). This allows uniform pressure to be applied to the individual power semiconductor components. The holding part 90 of the embodiment as shown in FIG. 14 can be mechanically coupled to the cooler 7 or the insulator 2 of the SMD circuit carrier 1 in the manner already described above.

The SMD circuit carrier in the previously described embodiments can also be one of those shown by way of example in FIGS. 8 and 9.

The method according to the invention is particularly suitable for power semiconductor device modules with a minimum amperage of 5 A or for a minimum voltage of 24 V. The method according to the invention is particularly suitable for this field of power electronics, since the laser-welded connection 16 allows for the high temperatures caused by the high amperages and voltages of the semiconductor components 4 and does not limit the performance and reliability of the circuit.

The semiconductor component 4 can be an active or passive semiconductor component. (Packaged) discrete power semiconductor components are used as active and passive semiconductor components, which can be selected according to the requirements of the circuit based on the corresponding parameters. The semiconductor chips they contain are designed to meet optimum performance and reliability requirements under the given cooling conditions. Preferably, these are standard semiconductor components with an electrical contact surface on the underside thereof, which are intended for SMD technology.

### List of Reference Signs

1 SMD circuit carrier
2 (first) insulator
2a (first) conductor track structure
3 contact point
4 power semiconductor component
4a electrically conductive base surface
5 connection element
6 coating
7 cooler
8 welding window
9 holding part
10 SMD circuit carrier
11 placement foil
12 adhesive
13 placement machine
14 metallic carrier plate
15 equipment plate
16 laser-welded connection
17 roll
18 laser beam
19 optical fiber
20 second insulator
20a second conductor track structure
21 melting area
22 fiber laser
23 coupling surface
24 scanner
25 screw
26 insulating material
27 frame
28 edge area
29 latch connection
90 holding part
91 elastic element
KB circular movement
WB wobbling movement

1-25. (canceled)

26. A method for producing a surface mounted device (SMD) power semiconductor component module, comprising the following steps:
providing an SMD circuit carrier equipped with contact points and an insulation;
providing at least one discrete power semiconductor component equipped with electrically conductive connection elements, comprising connection legs;
arranging the at least one discrete power semiconductor component, equipped with electrically conductive connection elements, on the side of the SMD circuit carrier equipped with the contact points, wherein the connection elements of the power semiconductor component contact the contact points of the SMD circuit carrier; and
connecting the connection elements to the respectively assigned contact points by laser welding, wherein between the at least one power semiconductor component and the SMD circuit carrier, a pressure contact for electrical and thermal contacting is additionally created,
wherein the pressure contact is created via a holding part by clamping the arrangement of power semiconductor component and SMD circuit carrier between the holding part and a counter bearing which is located on the installation side.

27. The method according to claim 26, wherein a printed circuit board, an IMS substrate or a lead frame is provided as the SMD circuit carrier.

28. The method according to claim 26, wherein the contact point and/or the connection element comprise copper or a copper alloy.

29. The method according to claim 26, wherein the connection element, in an area of the connection element in which the laser welding occurs, is configured to run parallel to the main extension surface of the SMD circuit carrier.

30. The method according to claim 26, wherein the connection legs comprise a stepped configuration.

31. The method according to claim 26, wherein the laser-welded connection is formed by a continuous melting area.

32. The method according to claim 26, wherein the laser-welded connection is performed by a wobbling laser beam.

33. The method according to claim 26, wherein the laser welding is performed using an IR laser.

34. The method according to claim 26, wherein at least one discrete power semiconductor component equipped with electrically conductive connection elements, comprising the plurality of power semiconductor components, is located between the SMD circuit carrier and a holding part.

35. The method according to claim 34, wherein the at least one discrete power semiconductor component equipped with electrically conductive connection elements, comprising the plurality of power semiconductor components, is positioned and fixed on the holding part prior to laser welding, or the holding part is placed on the at least one discrete power semiconductor component equipped with electrical connection elements, wherein on the plurality of power semiconductor components, prior to laser welding in order to fix the position.

36. The method according to claim 34, wherein the holding part has welding windows through which the laser welding occurs.

37. The method according to claims 34, wherein an elastic element is arranged between the at least one power semiconductor component and the holding part.

38. The method according to claim 37, wherein the elastic element is a silicone foam pad.

39. The method according to claim 34, wherein the at least one power semiconductor component, comprising a plurality of power semiconductor components, is first positioned in a predetermined arrangement and/or orientation and fixed on a self-adhesive placement foil, and the holding part is fixed on the at least one power semiconductor component, on the plurality of power semiconductor components, in the arrangement and/or orientation previously determined on the placement foil.

40. The method according to claim 26, wherein a multilayer SMD circuit carrier comprising at least a first insulator and a second insulator and a first conductor track structure and a second conductor track structure, is provided as the SMD circuit carrier, wherein the contact point is located on the first conductor track structure or the second conductor track structure.

41. The method according to claim 40, wherein the second insulator with the second conductor track structure is arranged laterally with respect to the semiconductor component.

42. The method according to claim 41, wherein
the contact point is located on the second conductor track structure;
the second insulator with the second conductor track structure is angled; and
connecting the connection elements to the respectively assigned contact points is performed by laser welding in an area of the second conductor track structure arranged parallel to the first insulator.

43. The method according to claim 26, wherein the SMD circuit carrier comprises a cooler.

44. The method according to claim 26, wherein the power semiconductor component is configured for a minimum amperage of 5 A or for a minimum voltage of 24 V.

45. The method according to claim 26, wherein the power semiconductor device is an active or passive semiconductor component.

46. The method according to claim 26, wherein the power semiconductor component has an electrically and thermally conductive base surface, which is contacted with the SMD circuit carrier by the pressure contact.

47. The method according to claim 26, wherein the electrically and thermally conductive base surface is equipped with a coating of silver or a silver alloy.

48. An SMD power semiconductor component module produced by the method according to claim 26.
